(19) United States
(12) Patent Application Publication
(10) Pub. No.: US 2014/0195851 A1
(43) Pub. Date: Jul. 10, 2014

(54) VOLTAGE TESTING DEVICE AND METHOD FOR POWER SUPPLY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAO HU, Shenzhen (CN)

(73) Assignees: HON HAI PRECISION INDUSTRY CO., LTD., New Taipei (TW); HONG FU JIN PRECISION INDUSTRY (Shenzhen) CO., LTD., Shenzhen (CN)

(21) Appl. No.: 14/015,714

(22) Filed: Aug. 30, 2013

(30) Foreign Application Priority Data
Jan. 5, 2013 (CN) 2013100021450

(51) Int. Cl. G01R 31/40

(52) U.S. Cl. CPC G01R 31/40
USPC 714/27

(57) ABSTRACT

The disclosure provides a voltage testing device and a method. The voltage testing method includes following steps. The computer sets initial setting parameters for an oscillograph. The computer receives initial testing parameters sent by the oscillograph, and sends a current voltage offset and a current voltage undulating value to the control unit according to the initial testing parameters. The oscillograph obtains voltage values of the power supply during a period of time, produces a voltage wave according to the voltage values, and sends the voltage wave and the voltage values to the computer. The computer displays the voltage wave and the voltage values to the computer.

### BACKGROUND

1. Technical Field

The present disclosure generally relates to a voltage testing device and method for a power supply.

2. Description of Related Art

After a computer is manufactured, an overall test is required to check the quality. The power supply test is one of the most important tests. A common method for testing the power supply is to use a conventional device to test the power supply and to record corresponding data manually, which is inefficient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a voltage testing device.

FIG. 2 is a flow chart of one embodiment of a voltage testing method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

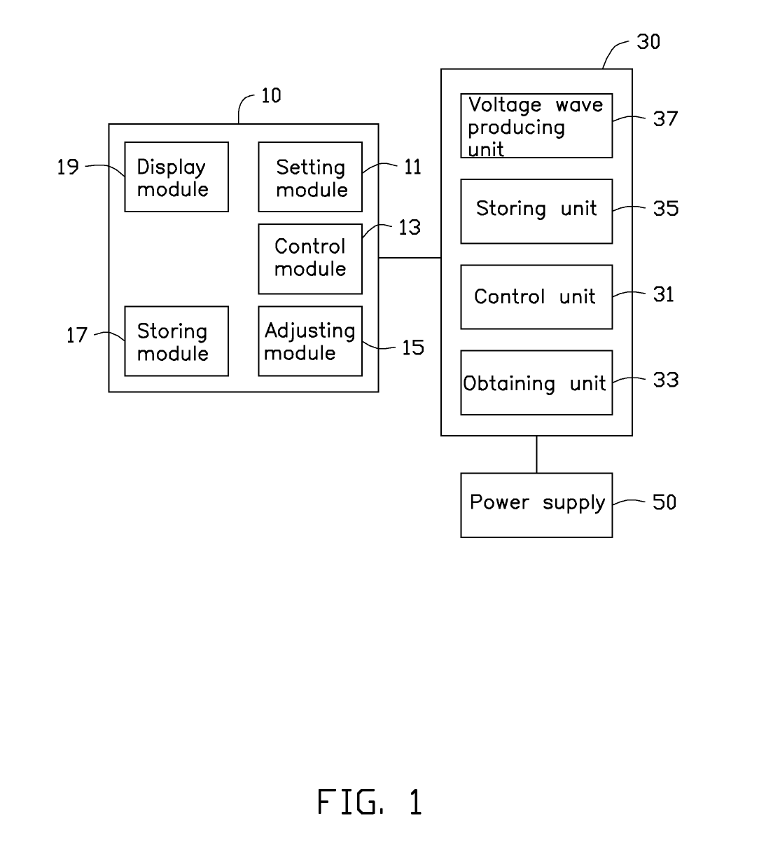

FIGS. 1 and 3 show a testing device 1 according to one embodiment. The testing device 1 includes a computer 10 and an oscillograph 30 connected to the computer 10. The oscillograph 30 includes a plurality of probes (not shown) for connecting to an output terminal of a power supply 50.

The computer 10 includes a setting module 11, a control module 13, an adjusting module 15, a storing module 17, and a display module 19.

The oscillograph 30 includes a control unit 31, an obtaining unit 33, a storing unit 35, and a voltage wave producing unit 37.

The setting module 11 is used for setting initial setting parameters, such as time reference, initial voltage offset, signal name, triggering reference, testing items, and initial voltage undulating value, for example, and storing the initial setting parameters to the storing module 17. The control module 13 is used for sending the initial setting parameters to the control unit 31. The control unit 31 is used for storing the initial setting parameters to the storing unit 35.

The obtaining unit 33 is used for obtaining the initial testing parameters when the oscillograph 30 is connected to the power supply 50. The initial testing parameters includes a voltage maximize value and a minimal value during a period of time. The control unit 31 is used for sending the initial testing parameters to the adjusting module 15. The adjusting module 15 is used for sending a current voltage offset and a current voltage undulating value to the control unit 31 of the oscillograph 30, and storing the current voltage offset and the current voltage undulating value to the storing module 17. The control unit 31 is used for storing the current voltage offset and the current voltage undulating value in the storing module 35.

The obtaining unit 33 is further used for obtaining voltage values during a period of time after the storing unit 35 stores the current voltage offset and the current voltage undulating value, and sending the voltage values during the period of time to the voltage wave producing unit 37. The voltage wave producing unit 37 is used for producing a voltage wave according to the voltage values during the period of time and sending the voltage wave and the voltage values during the period of time to control module 13 of the computer via the control unit 31. The control module 1 is further used for displaying the voltage wave and the voltage values during the period of time on the display module 19.

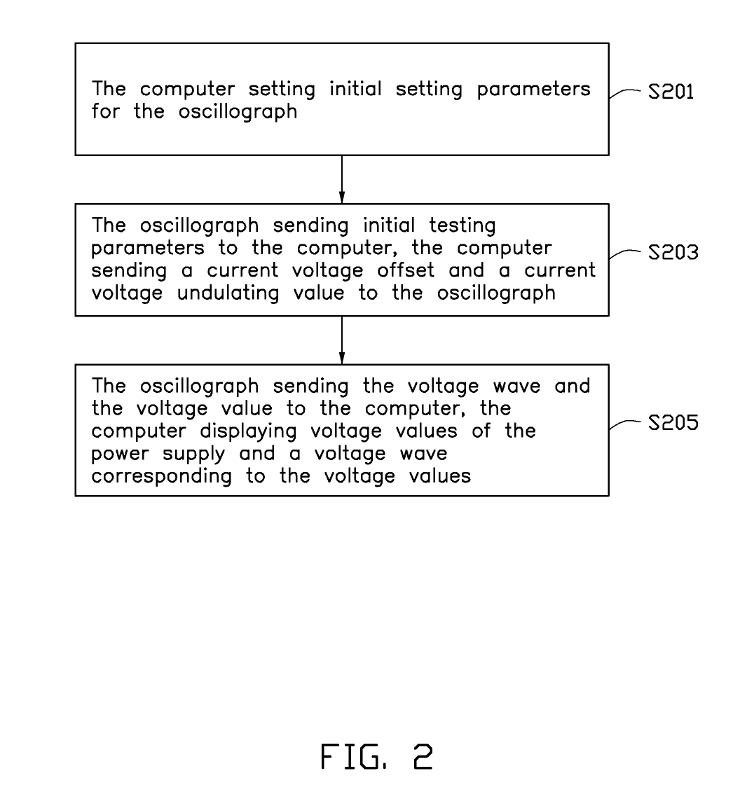

FIG. 2 shows that a voltage testing method for the power supply 50, according to one embodiment, includes following steps.

S201, the setting module 11 sets the initial setting parameters and stores the initial setting parameters to the storing module 17; the control module 13 sends the initial setting parameters to the control unit 31; and the control unit 31 stores the initial setting parameters in the storing unit 35.

S203, the obtaining unit 33 obtains initial testing parameters; the control unit 31 sends the initial testing parameters to the adjusting module 15; the adjusting module 15 sends a current voltage offset and a current voltage undulating value to the control unit 31 according to the initial testing parameters, and stores the current voltage offset and the current voltage undulating value to the storing module 17; and the control unit 31 stores the current voltage offset and the current voltage undulating value to the storing unit 35.

S205, the obtaining unit 33 obtains voltage values of the power supply 50 during a period of time, and sends the voltage values to the voltage wave producing unit 37; the voltage wave producing unit 37 produces a voltage wave according to the voltage values and sends the voltage wave and the voltage values to the control module 13 via the control unit 31; and the control module 31 displays the voltage wave and the voltage values on the display module 19.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A voltage testing device comprising:
a computer, the computer comprises a control module, an adjusting module, and a display module; and
an oscillograph, the oscillograph comprises a control unit, an obtaining unit, a storing unit, and a voltage wave producing unit;
wherein the control module is configured to send initial setting parameters to the control unit; the control unit is configured to store the initial setting parameters in the storing unit; the obtaining unit is configured to obtain initial testing parameters when the oscillograph is connected to a power supply; the control unit is further configured to send the initial testing parameters to the adjusting module; the adjusting module is configured to send a current voltage offset and a current voltage undulating value to the control unit according to the initial testing parameters; the obtaining unit is further configured to obtain voltage values of the power supply during a period time after the storing unit stores the current voltage offset and the current voltage undulating value, and to send the voltage values to the voltage wave producing unit; the voltage wave producing unit is configured to produce a voltage wave according to the voltage values, and to send the voltage wave and the voltage values to the control module; and the control module is further configured to display the voltage values and the voltage wave on the display module.

2. The voltage testing device of claim 1, wherein the computer further comprises a storing module, and the storing module is configured to store the current voltage offset and the current voltage undulating value.

3. The voltage testing device of claim 1, wherein the initial setting parameters comprises initial voltage offset and initial voltage undulating value.

4. The voltage testing device of claim 3, wherein the initial setting parameters further comprises time reference, a signal name, a triggering reference, and testing items.

5. The voltage testing device of claim 1, wherein the initial testing parameters comprise a voltage maximize value and a minimal value during another period of time.

6. A voltage testing method, applied in a voltage testing device, comprising:
a computer setting initial setting parameters for an oscillograph;
the computer receiving initial testing parameters sent by the oscillograph, and sending a current voltage offset and a current voltage undulating value to the oscillograph according to the initial testing parameters;
the oscillograph obtaining voltage values of a power supply during a period of time, producing a voltage wave according to the voltage values, and sending the voltage wave and the voltage values to the computer; and
displaying, by the computer, the voltage wave and the voltage values to the computer.

7. The voltage testing method of claim 6, wherein the current voltage offset and the current voltage undulating value is stored in the computer.

8. The voltage testing method of claim 6, wherein the initial setting parameters comprises initial voltage offset and initial voltage undulating value.

9. The voltage testing method of claim 8, wherein the initial setting parameters further comprises time reference, a signal name, a triggering reference, and testing items.

10. The voltage testing method of claim 6, wherein the initial testing parameters comprise a voltage maximize value and a minimal value during another period of time.
